(19) United States
(12) Patent Application Publication
(10) Pub. No.: US 2024/0292753 A1
(43) Pub. Date: Aug. 29, 2024

(54) PROCESS FOR ADDITIVE MANUFACTURING OF TERNARY-PHASE THERMOELECTRIC MATERIALS

(71) Applicants: Northwestern University, Evanston, IL (US); Battelle Energy Allliance, LLC, Idaho Falls, ID (US)

(72) Inventors: David C. Dunand, Evanston, IL (US); Donna P. Guillen, Idaho Falls, ID (US); Alexander Ernst Ludwig Proschel, Chicago, IL (US); Dennis S. Tucker, Idaho Falls, ID (US)

(21) Appl. No.: 18/589,066

(22) Filed: Feb. 27, 2024

Related U.S. Application Data
(60) Provisional application No. 63/487,495, filed on Feb. 28, 2023.

(51) Int. Cl. H10N 10/01; B22F 3/10; B22F 3/20; B22F 10/10; H10N 10/854

(52) U.S. Cl. CPC H10N 10/01; B22F 3/1021; B22F 3/1039; B22F 3/20; B22F 10/10; H10N 10/854; B22F 2301/15; B22F 2301/205; B22F 2301/30

(57) ABSTRACT

In certain aspects of the disclosure, a method includes creating ink specimens. The method includes solidifying, via solvent evaporation, the ink specimens to identify Ni powders and Ti powders. The method includes debinding and pre-sintering the Ni powders and the Ti powders to form a porous NiTi skeleton. The method includes infiltrating the porous NiTi skeleton with a transient liquid. The method includes reaction sintering the NiTi of the porous NiTi skeleton and the Sn to reactively form TiNiSn. Ternary-phase thermoelectric materials formed by the method are also provided.

### CROSS-REFERENCE TO RELATED APPLICATIONS

The present application claims the benefit of priority under 35 U.S.C. § 119 from U.S. Provisional Patent Application Ser. No. 63/487,495 entitled “PROCESS FOR ADDITIVE MANUFACTURING OF TERNARY-PHASE THERMOELECTRIC MATERIALS,” filed on Feb. 28, 2023, the disclosure of which is hereby incorporated by reference in its entirety for all purposes.

### STATEMENT OF FEDERALLY FUNDED RESEARCH OR SPONSORSHIP

This invention was made with government support under grant number DEAC07-05ID14517 awarded by the Department of Energy. The government has certain rights in the invention.

### TECHNICAL FIELD

The present disclosure generally relates to thermoelectric materials, and more specifically relates to processes for additive manufacturing of ternary-phase thermoelectric materials.

### BACKGROUND

Thermoelectric (TE) materials use temperature gradients to convert heat into electric power, thus enabling TE devices to capture waste heat with excellent long-term reliability and very low maintenance due to the lack of moving parts. However, widespread use is currently limited by suboptimal conversion efficiency, high material and processing costs, and mechanical fragility. One important determinant of TE device performance is conversion efficiency, as defined by the dimensionless thermoelectric figure of merit:

$$z T = {S}^{2} T / ρκ \qquad ( 1 )$$

where S is the Seebeck coefficient, ρ is the electrical resistivity, κ is the thermal conductivity and T is the absolute temperature. Although zT reflects the efficiency of a TE material, zT alone does not describe the overall performance of TE devices. Other properties, e.g., electrical and thermal resistance of the TE leg, are critical to device performance. Thermal and electrical resistances are, in turn, strongly influenced by TE leg shape and size. As traditional synthesis techniques for TE materials are very geometrically restrictive, they result in TE legs typically limited to cuboidal shape. The traditional process also relies primarily on step-wise dicing of a larger ingot which can waste up to 50% of costly TE material through kerf loss. These geometric restrictions strongly constrain the design of TE devices, ultimately limiting overall device performance. It has been shown that power generation for TE devices can be increased using hourglass, hollow, or layered TE leg geometries. Additionally, shape limitations pose a problem for many applications such as waste-heat scavenging on curved surfaces. TiNiSn is an example of such a TE material with excellent material properties constrained by geometric restrictions imposed by current manufacturing methodologies.

Half-Heusler-structured TiNiSn is a promising intermediate-temperature (600-800 K) n-type TE material, making it suitable for a wide range of energy-harvesting applications. TiNiSn is of interest primarily due to its high zT (with reported values up to 1.0), non-toxicity and low cost. Additionally, TiNiSn demonstrates high thermal stability, is mechanically robust, and has a large TE power-factor (PF=S²/ρ), all of which are vital for practical implementation in TE devices. Due to its structure, TiNiSn can also be easily doped through vacancy or substitution defects to optimize zT. However, despite these attractive properties, limitations in current TiNiSn manufacturing methods pose a major challenge in the development of new TiNiSn-based TE devices.

Synthesis of TiNiSn can be difficult, primarily due to the discrepancy between elemental melting temperatures as well as a narrow phase stability window. Combined with slow diffusion kinetics and high melting point binary phases and ternary Heusler phase (TiNi₂Sn), presence of secondary phases and sample heterogeneity are common. Current synthesis techniques include arc-melting (AR), inductive levitation melting (LM), hot isostatic pressing (HIP), spark plasma sintering (SPS), microwave synthesis (MW), long term annealing (AN) or a combination of techniques. However, unlike additive manufacturing (AM), these fabrication methods do not allow for geometric freedom.

The description provided in the background section should not be assumed to be prior art merely because it is mentioned in or associated with the background section. The background section may include information that describes one or more aspects of the subject technology.

### SUMMARY

According to certain aspects of the present disclosure, a method for additive manufacturing of ternary-phase thermoelectric materials is provided. The method includes creating ink specimens. The method includes solidifying, via solvent evaporation, the ink specimens into Ni powders and Ti powders. The method includes debinding and pre-sintering the Ni powders and the Ti powders to form a porous NiTi skeleton. The method includes infiltrating the porous NiTi skeleton with a transient liquid. The method includes reaction sintering NiTi of the porous NiTi skeleton and the transient liquid to reactively form TiNiSn.

According to other aspects of the present disclosure, a ternary-phase thermoelectric material is provided. The ternary-phase thermoelectric material includes a structure. The is formed by creating ink specimens, solidifying, via solvent evaporation, the ink specimens into Ni powders and Ti powders, debinding and pre-sintering the Ni powders and the Ti powders to form a porous NiTi skeleton, infiltrating the porous NiTi skeleton with a transient liquid, and reaction sintering NiTi of the porous NiTi skeleton and the transient liquid to reactively form TiNiSn.

According certain other methods of the present disclosure, a method for additive manufacturing of ternary-phase thermoelectric materials is provided. The method includes creating ink specimens. The method includes solidifying, via solvent evaporation, the ink specimens into Ni powders and Ti powders. The method includes debinding and pre-sintering the Ni powders and the Ti powders to form a porous NiTi skeleton. The method includes infiltrating, via capillary forces, the porous NiTi skeleton with a liquid Sn. The method includes reaction sintering NiTi of the porous NiTi skeleton and the Sn to reactively form TiNiSn.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### BRIEF DESCRIPTION OF DRAWINGS

The disclosure is better understood with reference to the following drawings and description. The elements in the figures are not necessarily to scale, emphasis instead being placed upon illustrating the principles of the disclosure. Moreover, in the figures, like-referenced numerals may designate to corresponding parts throughout the different views.

FIG. 1A is schematic flow chart for a 3D ink printing approach, according to certain aspects of the disclosure, illustrating the steps of (i) ink containing binder and Ni+Ti powders is 3D-printed or cast at room temperature into a solid preform and solidified via solvent evaporation, (ii) preform is debound and pre-sintered, to form porous equiatomic NiTi which is (iii) infiltrated with liquid Sn and (iv) reaction-sintered to synthesize nearly dense equiatomic TiNiSn. An optional post-annealing step to further homogenize the specimen is not shown.

FIG. 1B illustrates a scanning electron microcopy (SEM) micrograph of polished cross-section of NiTi preform from FIGS. 2A-2C, following debinding and pre-sintering.

FIGS. 1C and 1D illustrate EDS maps for Ni and Ti, respectively. EDS indicates the skeleton is primarily equiatomic NiTi with regions of off-equiatomic composition.

FIG. 2A is a cross-sectional image of a cast thin plate illustrating a low magnification image of thin NiTi plate following debinding and Ni+Ti pre-sintering, showing homogenous porosity of ˜55%.

FIG. 2B is a cross-sectional image of a cast thin plate illustrating a high magnification image of thin NiTi plate showing interconnected porosity.

FIG. 2C is a cross-sectional image of a TiNiSn thin plate following Sn infiltration and reaction at 1000° C. for 4 h, showing nearly single-phase microstructure with remanent porosity from excess porosity prior to infiltration (55 vs. 48.5%).

FIG. 2D is an optical micrograph of polished cross-section of printed NiTi lattices following debinding and Ni+Ti pre-sintering, where debinding profile is kept constant and only pre-sintering is changed, 1150° C. for 90 min. Such pre-sintering profile was selected for the process, due to consistent optimal porosity fraction and limited oxidation achieved by reducing sintering time.

FIG. 2E is an optical micrograph of polished cross-section of printed NiTi lattices following debinding and Ni+Ti pre-sintering, where debinding profile is kept constant and only pre-sintering is changed, 1125° C. for 90 min.

FIG. 2F is an optical micrograph of polished cross-section of printed NiTi lattices following debinding and Ni+Ti pre-sintering, where debinding profile is kept constant and only pre-sintering is changed, 1100° C. for 90 min.

FIG. 2G is an optical micrograph of polished cross-section of cast thin NiTi plates, following debinding and Ni+Ti pre-sintering, where debinding profile is kept constant and only pre-sintering is changed, 1000° C. for 150 min.

FIG. 2H is an optical micrograph of polished cross-section of cast thin NiTi plates, following debinding and Ni+Ti pre-sintering, where debinding profile is kept constant and only pre-sintering is changed, 900° C. for 240 min.

FIG. 3A is a chart illustrating XRD spectra, in pre- and post-annealing states, of the same TiNiSn cast plate. Beside the main TiNiSn peaks, peaks for Sn and Ni₃Sn₄ are present in both cases, with annealing causing additional formation of TiO₂.

FIG. 3B is a cross-sectional optical micrograph of thick (>3 mm) cast NiTi plates following debinding and Ni+Ti pre-sintering, 450° C. for 60 min. Heterogenous porosity occurs in the form of denser core.

FIG. 3C is a cross-sectional optical micrograph of thick (>3 mm) cast NiTi plates following debinding and Ni+Ti pre-sintering, 1000° C. for 150 min. Heterogenous porosity occurs in the form of a highly porous core.

FIG. 4A is a SEM micrograph of cast thin TiNiSn plate before annealing, with secondary phases identified via EDS analysis. Higher magnification view shows (sub-)micron TiO₂ particles present in Ni₃Sn₄ region (they are also associated with Sn regions).

FIG. 4B is a cross-sectional SEM micrograph of post-annealed, cast thin TiNiSn plate. No measurable densification occurred during this long-term annealing.

FIG. 5A is chart illustrating temperature dependence of thermoelectric property of thermal conductivity for a cast TiNiSn plate, tested before and after annealing for one week at 850° C. Filled and open symbols indicate data collected during heating and cooling, respectively; solid lines represent polynomial best-fit curves used to calculate zT from Eq. (1). Error bars are smaller than data points for thermal conductivity.

FIG. 5B is chart illustrating temperature dependence of thermoelectric property of electrical resistivity for a cast TiNiSn plate, tested before and after annealing for one week at 850° C. Filled and open symbols indicate data collected during heating and cooling, respectively; solid lines represent polynomial best-fit curves used to calculate zT from Eq. (1). Error bars are smaller than data points for thermal conductivity.

FIG. 5C is chart illustrating temperature dependence of thermoelectric property of Seebeck coefficient for a cast TiNiSn plate, tested before and after annealing for one week at 850° C. Filled and open symbols indicate data collected during heating and cooling, respectively; solid lines represent polynomial best-fit curves used to calculate zT from Eq. (1). Error bars are smaller than data points for thermal conductivity.

FIG. 5D is chart illustrating temperature dependence of thermoelectric property of figure of merit zT for a cast TiNiSn plate, tested before and after annealing for one week at 850° C. Filled and open symbols indicate data collected during heating and cooling, respectively; solid lines represent polynomial best-fit curves used to calculate zT from Eq. (1). Error bars are smaller than data points for thermal conductivity.

FIG. 5E is a cross-sectional SEM micrograph of Sn infiltration front showing gradient in Sn infiltration within the NiTi preform. White dotted lines divide the three regions of infiltration: (i) partial infiltration showing some TiNiSn formation, with unreacted Ni and Ti also present as denoted by white arrow, (ii) Sn wetting, showing thin layer of Sn coating the NiTi skeletal structure but minimal formation of TiNiSn, (iii) no infiltration, showing complete absence of Sn and the original porous NiTi skeleton.

FIG. 5F is an EDS map of FIG. 5E for Sn. White dotted lines divide the three regions of infiltration: (i) partial infiltration showing some TiNiSn formation, with unreacted Ni and Ti also present as denoted by white arrow, (ii) Sn wetting, showing thin layer of Sn coating the NiTi skeletal structure but minimal formation of TiNiSn, (iii) no infiltration, showing complete absence of Sn and the original porous NiTi skeleton.

FIG. 5G is an EDS map of FIG. 5E for Ti.

FIG. 5H is an EDS map of FIG. 5E for Ni.

FIG. 6A is a chart illustrating temperature dependence of zT for our pre-annealing cast thin TiNiSn plate and TiNiSn samples from literature synthesized using various techniques: arc melting (AR), annealing (AN), reaction sintering (RS), hot isostatic pressing (HIP), microwave synthesis (MW), spark plasma sintering (SPS) and microwave sintering (MWS).

FIG. 6B illustrates an isothermal Ti—Ni—Sn phase diagram at 800° C. Arrows indicate reaction sequence from elemental Ti and Ni to NiTi then to TiNiSn upon reaction with infiltrated Sn.

FIG. 7A is a diagram illustrating geometry of layered TE leg where measurements are in mm; sections (W,N) and struts (H,V) are described below.

FIG. 7B is a photograph of layered TE leg in an as-printed state.

FIG. 7C is a photograph of layered TE leg in reacted state.

FIG. 7D is a chart illustrating temperature dependence of Seebeck coefficient for pre-annealing cast thin TiNiSn plate of FIG. 5C and for layered TiNiSn TE leg of FIG. 7C. Filled and open symbols indicate data collected during heating and cooling, respectively and solid lines represent polynomial best-fit curves.

FIG. 7E is a chart illustrating thermal conductivity for a cast TiNiSn plate before and after annealing for one week at 850° C.

FIG. 7F is a chart illustrating lattice thermal conductivity for a cast TiNiSn plate before and after annealing for one week at 850° C.

FIG. 8A is a diagram illustrating meshed FEM model with color contours indicating gradients of temperature for (a) square prism, (b) truncated square pyramid, (c) center-hyperboloid, (d) linear-hyperboloid, (e) curve-hyperboloid, and (f) layered legs.

FIG. 8B is a diagram illustrating meshed FEM model with color contours indicating gradients of electrical potential for (a) square prism, (b) truncated square pyramid, (c) center-hyperboloid, (d) linear-hyperboloid, (e) curve-hyperboloid, and (f) layered legs.

FIG. 8C is a cross-sectioned micrograph of ink-printed TE leg illustrating low magnification optical micrograph of porous NiTi preform, following debinding and Ni+Ti pre-sintering, showing homogenous porosity, equivalent to cast thin plate.

FIG. 8D is a cross-sectioned micrograph of ink-printed TE leg illustrating high magnification micrograph view showing single-phase, interdiffused NiTi skeleton and open porosity.

FIG. 8E is a cross-sectioned micrograph of ink-printed TE leg illustrating nearly single-phase microstructure of TiNiSn TE leg following Sn infiltration and homogenization, with remanent porosity (due to excess porosity in the NiTi preform) and low fraction of secondary phases (darker and lighter contrast).

FIG. 9A is a chart illustrating temperature profile across the thermoelectric legs with different geometries.

FIG. 9B is a chart illustrating open circuit voltage versus short circuit current for all leg geometries.

FIG. 9C is a chart illustrating output power for all leg geometries.

FIG. 9D is a chart illustrating output electrical power normalized by the projected area of the legs.

FIG. 9E is a chart illustrating a XRD spectra for pre-annealed cast thin TiNiSn plate and layered TE leg. Unlabeled peaks correspond to TiNiSn peaks. Secondary phases Sn and Ni₃Sn₄ are present in both cases and TiO₂ is present in layered TE leg, due to higher surface area enabling oxidation during NiTi pre-sintering step.

FIG. 10A is a schematic illustrating a cuboid geometry for FEM modeling. All measurements are in mm.

FIG. 10B is a schematic illustrating a center hyperboloid geometry for FEM modeling. All measurements are in mm.

FIG. 10C is a schematic illustrating a linear hyperboloid geometry for FEM modeling. All measurements are in mm.

FIG. 10D is a schematic illustrating a curve hyperboloid geometry for FEM modeling. All measurements are in mm.

FIG. 10E is a schematic illustrating a truncated square pyramid geometry for FEM modeling. All measurements are in mm.

FIG. 10F is a schematic illustrating a layered constructed geometry for FEM modeling. All measurements are in mm.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

The detailed description set forth below is intended as a description of various implementations and is not intended to represent the only implementations in which the subject technology may be practiced. As those skilled in the art would realize, the described implementations may be modified in various different ways, all without departing from the scope of the present disclosure. Accordingly, the drawings and description are to be regarded as illustrative in nature and not restrictive.

In certain aspects, the disclosed technology provides a 3D ink printing approach for synthesizing TiNiSn combining liquid infiltration and reaction sintering via a transient liquid phase and subsequent solid-state diffusion. Use of a transient liquid phase and reaction sintering of elemental powders is conducive with ink printing and forms homogenous alloys ink-printed from elemental powders, e.g., in inks containing elemental Ni, Mn, and Ga powders printed at ambient temperature: upon heating, Ga melts, wets the Ni and Mn powders and reacts with them to form the Ni₂MnGa phase. The disclosed 3D ink printing approach relies on a transient liquid phase being introduced via an external infiltration step, rather than being present in the original printed ink.

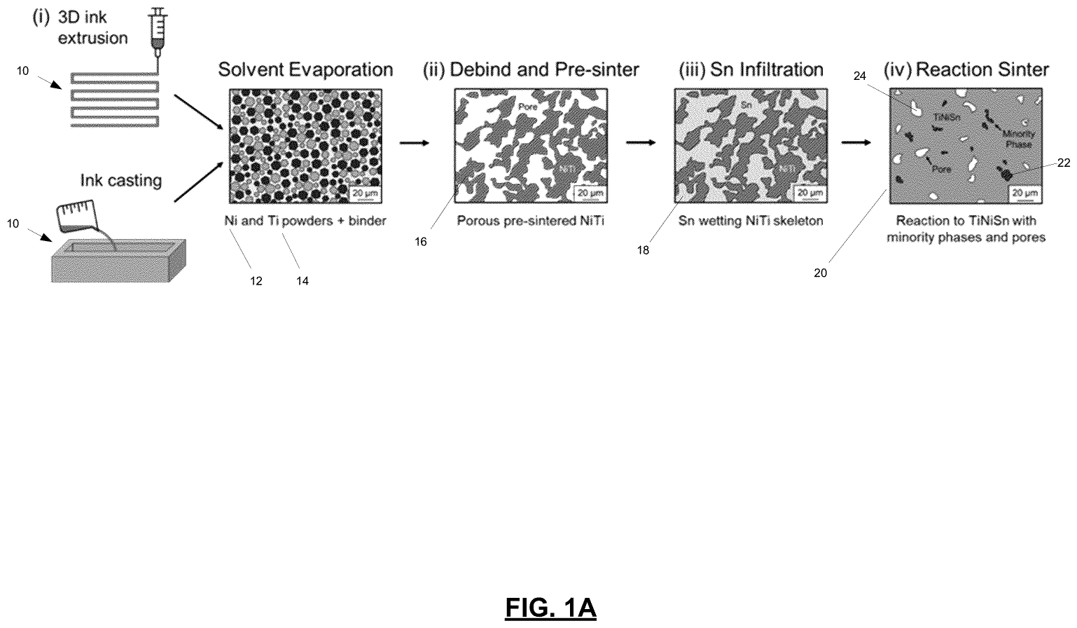

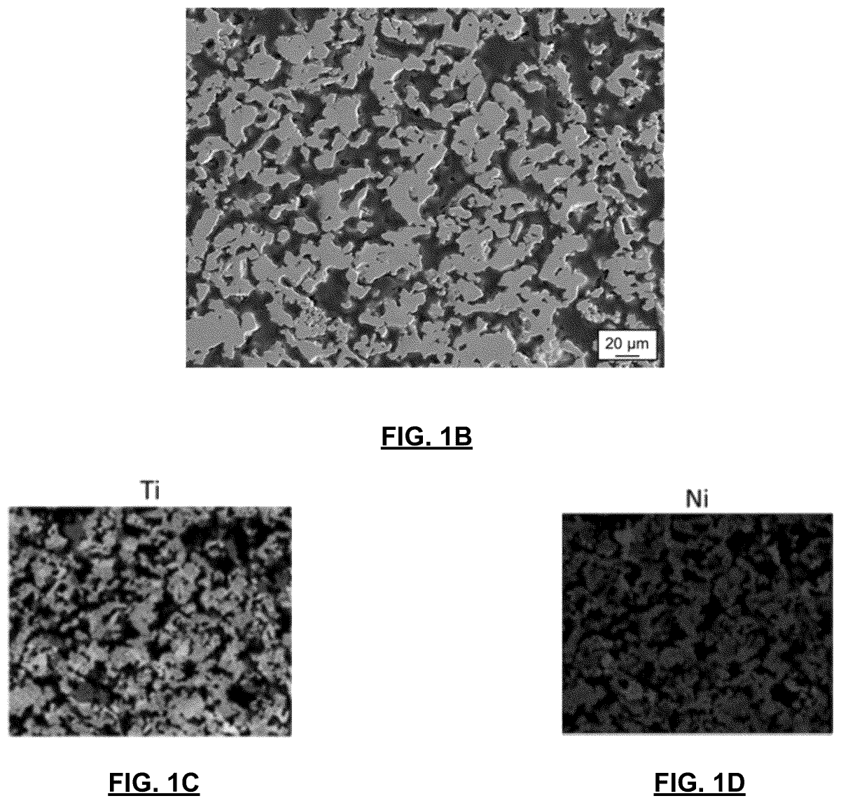

As shown in FIG. 1A, an ink specimen 10 is created via casting or 3D extrusion of inks which are then solidified into Ni powders 12 and Ti powders 14 via solvent evaporation. In a second step, debinding and pre-sintering of Ni and Ti powder inks forms a porous NiTi skeleton 16, with porosity as close as possible to the volume of Sn required to achieve equiatomic TiNiSn (48.5 vol %). In a third step, capillary forces draw a transient liquid 18, such as liquid Sn, into the NiTi skeleton 16, which is fully infiltrated by the wetting melt. Subsequent interdiffusion between NiTi and Sn (first in a transient liquid and later in the solid state) allows for near complete reaction to TiNiSn 20 with minimal secondary phases and low residual porosity. The disclosed approach—combining powder sintering, liquid metal infiltration, and reaction synthesis—can be used for TiNiSn. The disclosed technology demonstrates that both bulk specimens (i.e., TiNiSn plates) cast from a precursor ink, and geometrically-complex objects (i.e., TiNiSn lattices) created by 3D-ink extrusion printing, which each exhibit thermoelectric properties comparable to those achieved via traditional synthesis techniques.

### Ink Preparation, Casting, and Printing

Inks were prepared on ink extrusion of metallic powders. The inks comprised (i) 12 g of dichloromethane solvent (DCM, Fisher Chemical); (ii) 0.44 g of polystyrene binder (M_{W}=350 k, Sigma-Aldrich); (iii) 0.6 g of ethylene glycol butyl ether surfactant (EGBE, Sigma-Aldrich); and (iv) 0.1 g of dibutyl phthalate plasticizer (DBP, Sigma-Aldrich). Following polystyrene dissolution, 3.32 g of Ni powder (5 μm, 99.5%, US Nano) and 2.82 g of Ti powder (5 μm, 99%, US Nano) were added to the ink, creating a 49-51 at % ratio, respectively. Inks were then thickened via DCM evaporation at 60° C. During thickening, the inks were mixed every 5-10 minutes using a vortex mixer to ensure homogeneity. Once viscosities suitable for casting or printing were achieved, inks were either cast into rectangular molds (5×10 cm) to a thickness of ˜3 mm and left to solidify or they were ink-printed into complex architectures using 580 μm conical nozzles on either, for example, a 3D-Bioplotter (EnvisionTec, Germany) or BioBot Basic (Advanced Solutions, USA).

### TiNiSn Synthesis

Once solidified, cast or printed green bodies were placed in a boron-nitride-coated alumina crucible and subjected to debinding and pre-sintering in an alumina tube furnace. Heating occurred under ˜0.5 l/min of H₂ (99.999%) between 20 and 450° C. and under ˜0.5 l/min of Ar (99.999%) between 450 and 1000° C. at a rate of 10° C./min, with three isothermal periods: (i) at 150° C. for 30 min (to remove all DCM), (ii) at 450° C. for 60 min (to burn off the polymer binder), and (iii) at 1000° C. for 150 min (to partially sinter the Ni and Ti powders). After cooling to 20° C. at a rate of 5° C./min, flattened Sn shot (99.8%, Alfa Aesar) was placed on top of the pre-sintered NiTi samples, with a mass corresponding to an equiatomic composition with respect to the Ni content. The specimens were heated to 1000° C., kept at that temperature for 4 hours to achieve reaction between the NiTi phase and the Sn melt, and cooled to 20° C. under Ar flowing at ˜0.5 l/min, in the same crucible and tube furnace as for sintering, using heating/cooling rates of 10 and 5° C./min, respectively. With the goal to further homogenize and densify them, some infiltrated samples were annealed for 7 days at 850° C. in a vacuum tube furnace (with residual pressure of ˜2×10⁻⁶ torr). Titanium shim stock getters were utilized during all heat treatments to reduce oxidation.

### Characterization

Porosity was measured by thresholding on cross-sectional micrographs using ImageJ software, for example. Optical microscopy was conducted on an inverted light microscope (for example, Nikon MA200 Eclipse). Scanning electron microcopy (SEM) and energy-dispersive X-ray spectroscopy (EDS) were completed using, for example, a FEI Quanta 650 and JEOL JSM-7900FLV, both equipped with an Oxford EDS detector for example. X-ray diffraction (XRD) was performed using pure Cu-Kα₁ radiation on, for example, a Rigaku Smartlab 3 kW Gen2 and Rigaku Ultima IV. Thermal diffusivity (D_{T}) was measured using laser flash analysis (LFA) (Netzsch LFA 457, Germany) under flowing Ar from 20 to 600° C. Thermal conductivity (κ) was calculated as κ=D_{T}ρCₚ, where Cₚ is the Dulong-Petit approximation of heat capacity (Cₚ=3R, where R is the universal gas constant) and ρ is the mass density. Seebeck coefficient and electrical resistivity were simultaneously measured using a ZEM-3 apparatus (Ulvac Riko, Inc.) under a He atmosphere from 20 to 600° C.

### Microstructural Characterization

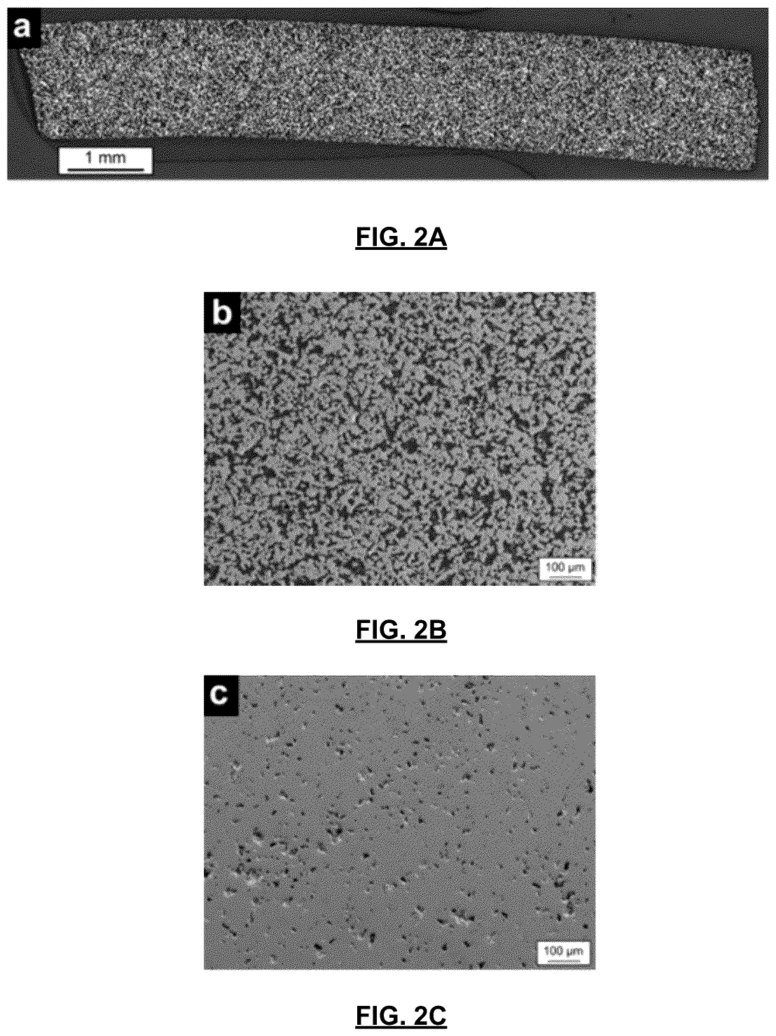

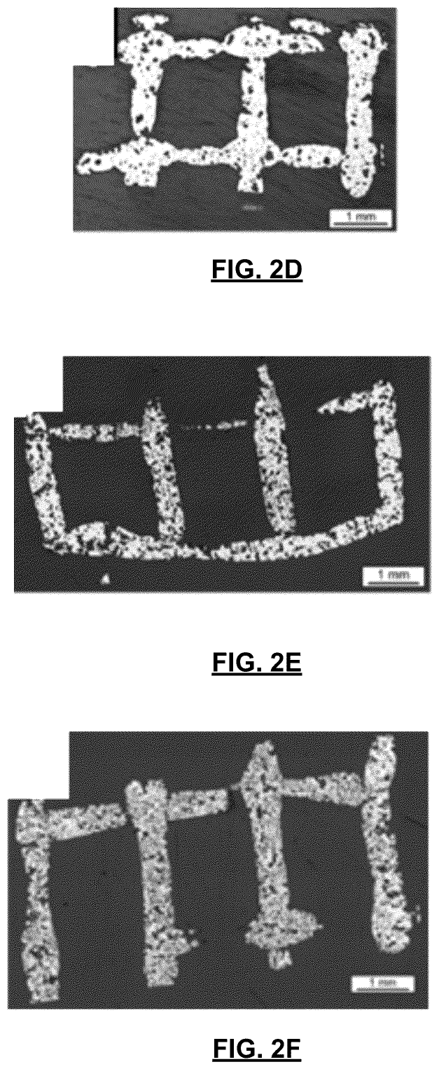

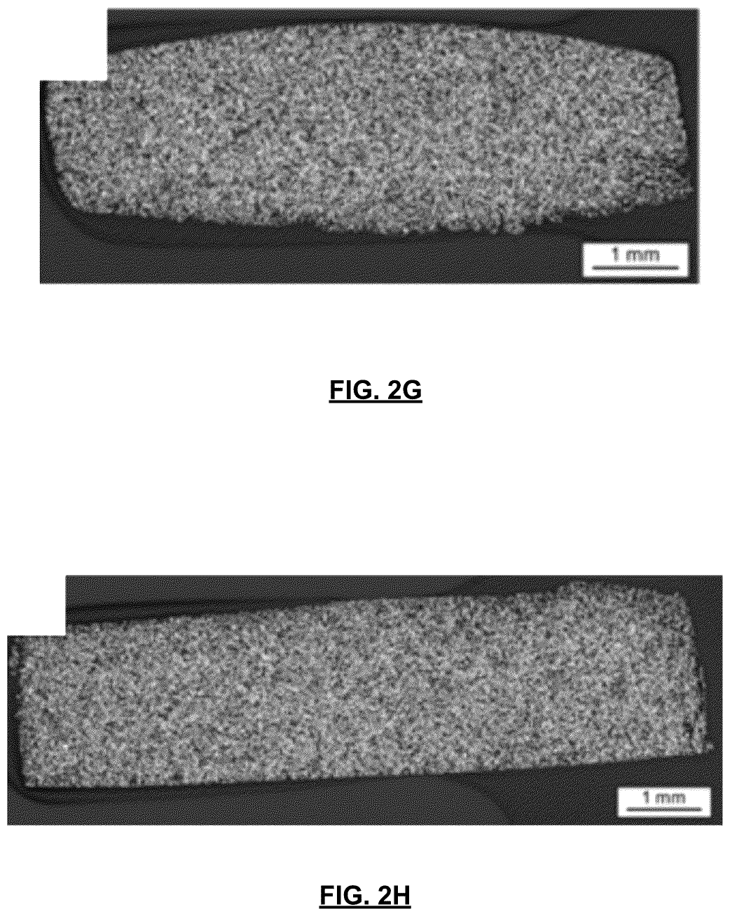

To characterize the synthesis process, SEM and optical microscopy was performed after each process stage. FIGS. 2A-2C show representative images of the resulting microstructure following each step used for a cast thin plate. Following debinding and Ni+Ti pre-sintering at 450° C. under H₂ and at 1000° C. under Ar, respectively, a NiTi skeleton with homogenous, open porosity of approximately 55 vol % was achieved, as shown in FIG. 2A; to achieve the ideal volume of space needed for equiatomic Sn infiltration, the NiTi skeleton optimally should have 48.5% porosity. Minimal to no linear shrinkage occurred during debinding and Ni+Ti pre-sintering.

A magnified image following debinding and Ni+Ti pre-sintering, as shown in FIG. 2B, indicates an interconnected NiTi skeletal structure. The observed thin ligaments enable complete interdiffusion between Ti and Ni, and subsequent reaction sintering during Sn infiltration. EDS analysis, shown in FIGS. 1B-1D, confirms the NiTi composition following debinding and pre-sintering but indicates the presence of some off-equiatomic regions.

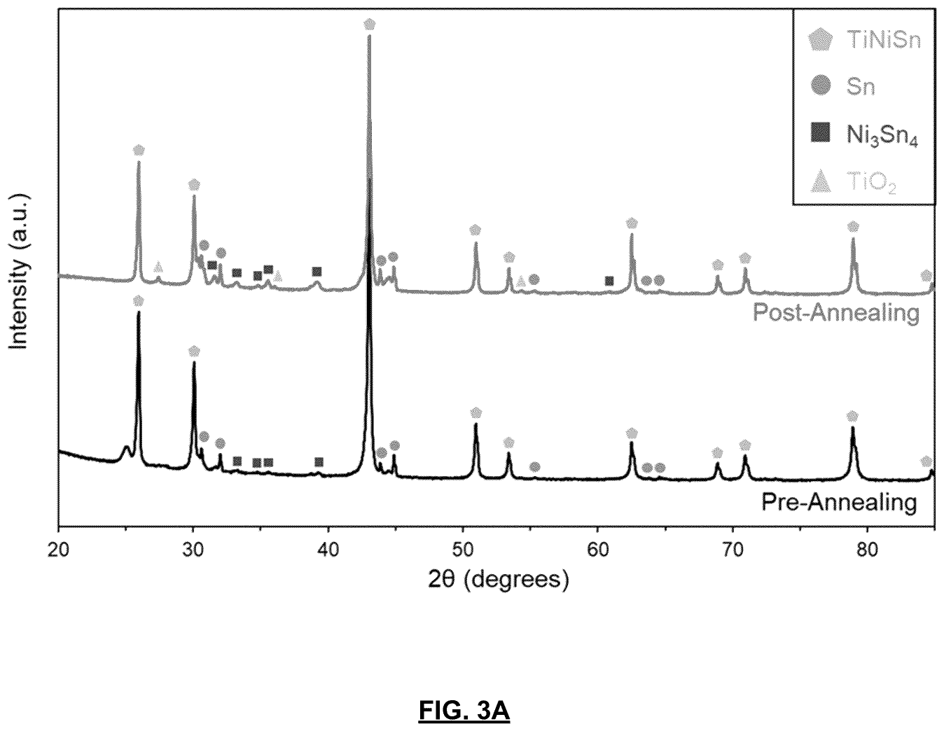

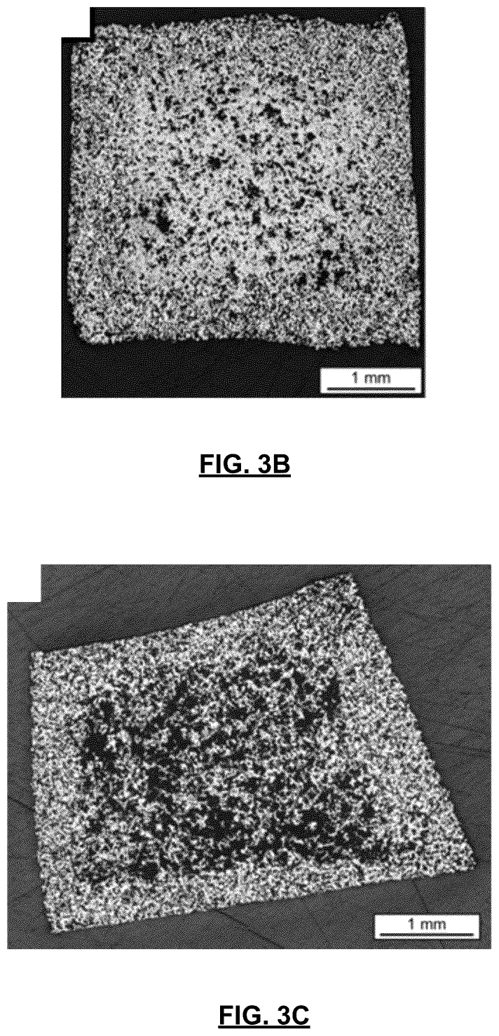

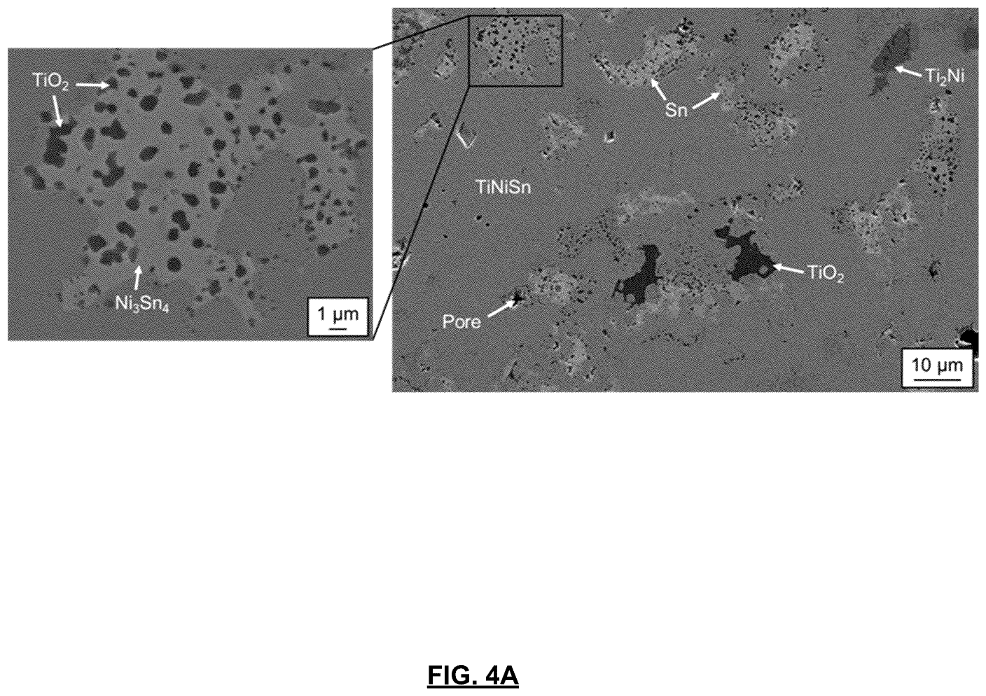

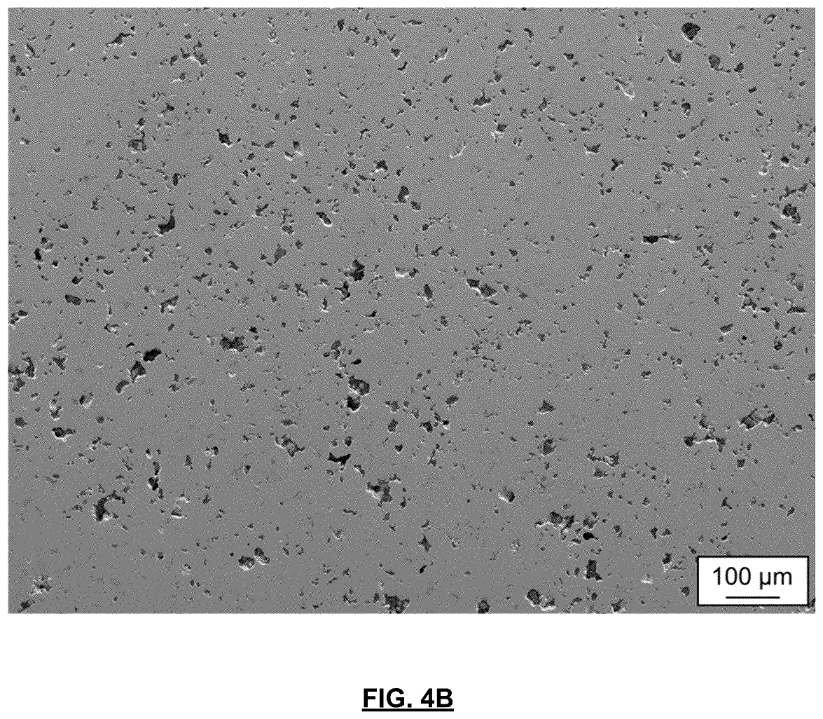

Multiple pre-sintering temperature profiles were tested, with resulting microstructures shown in FIGS. 2D-2F. Optimal porosity (near 48.5%) and minimal oxidation of Ti powders was achieved with pre-sintering at 1000° C. for 150 min. Green body size also significantly impacted the homogeneity of porosity following debinding and pre-sintering (see FIGS. 3B and 3C). Plates with the thickness>3 mm showed marked gradients in porosities, most probably due to uneven burn-out of binder between the center and surface of the plates.

The microstructure following Sn infiltration and interdiffusion at 1000° C. is shown in FIG. 2C. The specimen exhibits a homogenous, nearly-single-phase microstructure which is ˜91% dense. Remnant porosity is attributed to a slight excess in porosity following debinding and Ni+Ti pre-sintering (55% vs. optimal 48.5%) preventing the available Sn to fully fill the open pores of the NiTi pre-sintered specimen. Excess porosity is preferred to deficient porosity, as the latter (unlike the former) leads to some Sn remaining on the surface of the specimen, and thus a departure from stoichiometry after interdiffusion, creating secondary phases. Minimal to no further densification occurred during the week-long annealing process at 850° C. (see FIG. 4B).

### Phase Characterization

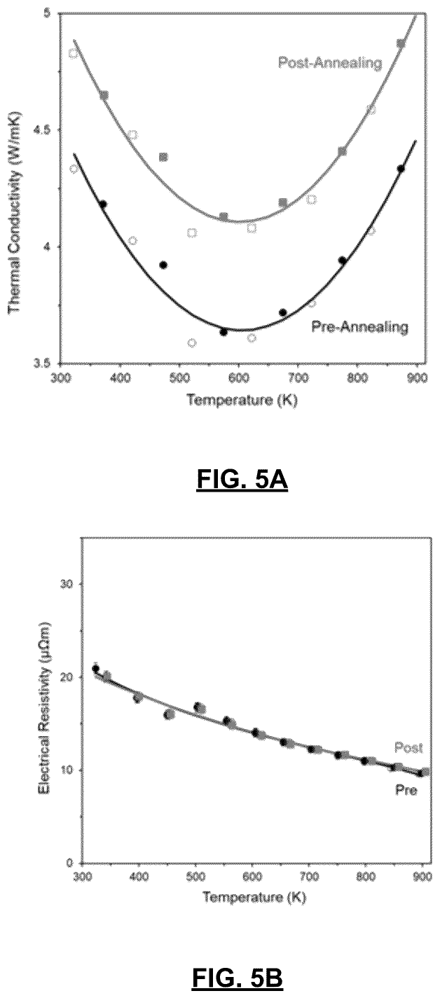

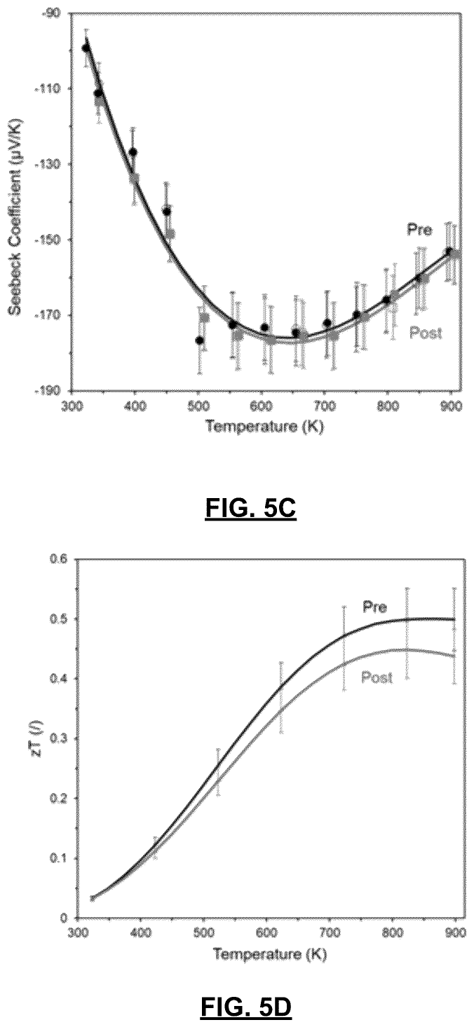

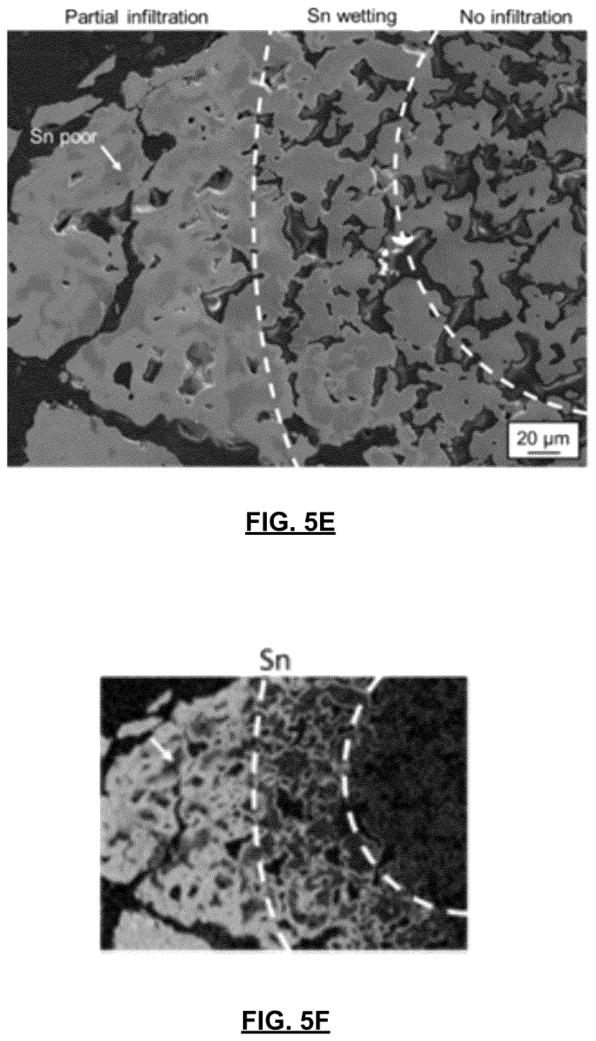

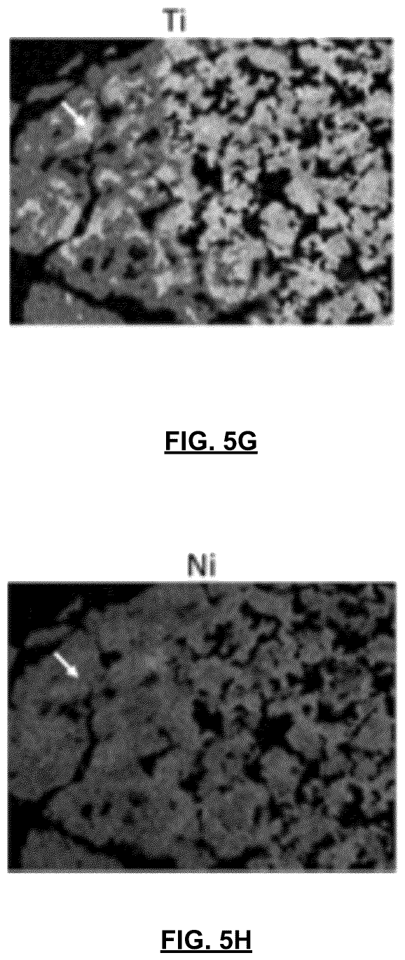

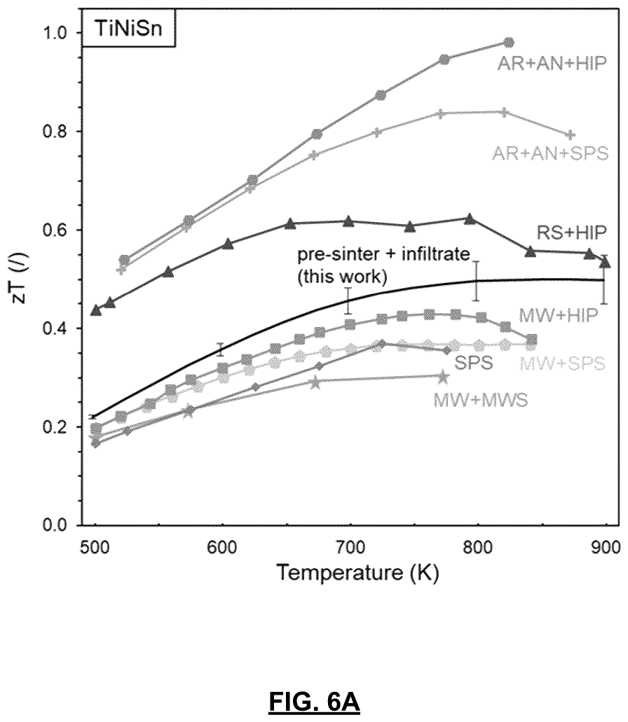

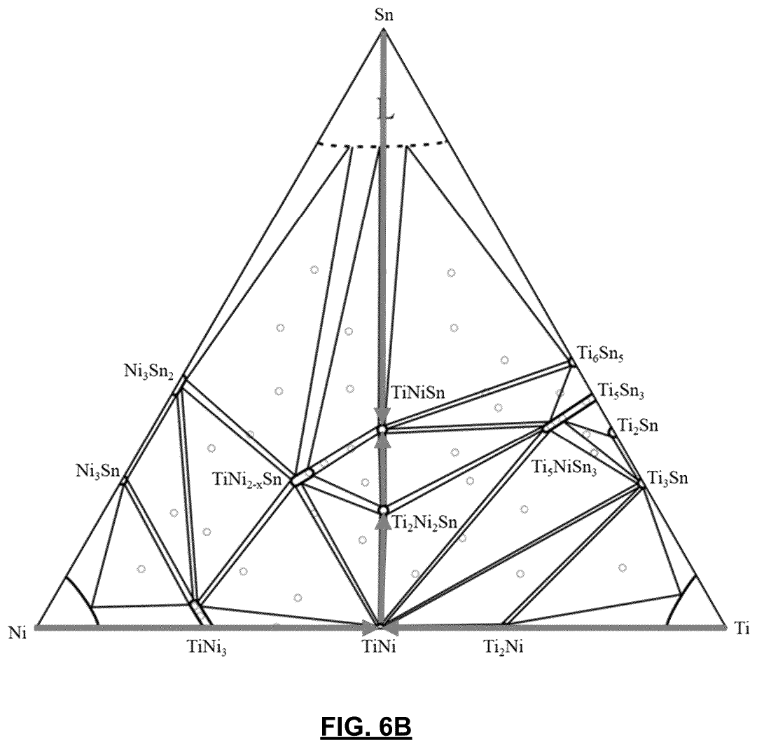

As Sn infiltrates through capillary forces, it wets the surfaces of the NiTi skeleton and begins to react at the interface to form TiNiSn, following the reaction sequence indicated by the arrows in the Ti—Ni—Sn phase diagram (see FIGS. 5E-5H). Thus, when NiTi is in contact with liquid Sn, TiNiSn forms via interdiffusion of Ni, Ti and Sn. If regions exist which are slightly off-stoichiometric, such as Ni-rich phase Ni₃Ti or the Ti-rich phase, Ti₂Ni the formation of secondary phases is expected.

Further SEM/EDS analysis allows for compositional characterization of minority phases and provides insights into their formation. FIG. 4A shows a particularly inhomogeneous region of a pre-annealing cast TiNiSn plate, selected here as it displays all identifiable secondary phases observed in both pre- and post-annealing cases (most regions are much more homogenous and do not show all phases).

In agreement with the XRD spectrum of FIG. 3A, FIG. 4A shows that the TiNiSn matrix contains small amounts of Sn, Ni₃Sn₄ and TiO₂ as minority phases. Furthermore, Ti₂Ni is also identified, and may be a remanent of unreacted NiTi skeleton, possibly in regions where a local excess of Ti was present. The Ni deficiency in these unreacted regions could also be attributed to the higher solubility of Ni, as compared to Ti, in molten Sn at 1000° C., as shown by the binary phase diagrams. This may contribute to some regions with excess Sn forming Ni₃Sn₄ during infiltration. From the presence of TiO₂, it can be concluded that not only does oxidation occur during annealing but TiO₂ forms during reaction sintering as well. A plausible explanation is that oxygen previously dissolved in Ti is rejected from TiNiSn as it forms and reacts with Ti to form TiO₂ which is more stable than oxides of Sn and Ni. This phenomenon appears to occur on two size scales, forming coarse TiO₂ precipitates (˜10 μm in size) within the TiNiSn matrix, and micron- to submicron precipitates in minority regions of pure Sn or Ni₃Sn₄. As mentioned previously, loss of Ti to TiO₂ contributes to the formation of Ni₃Sn₄, since localized regions depart from the equiatomic Ni/Ti stoichiometry, as shown in the inlay in FIG. 4A. Oxidation is difficult to mitigate when using micron-scale powders: as-received Ti powder contained 0.35 wt. % (1.04 at. %) oxygen, as measured via ion coupled plasma (ICP) analysis at Westmoreland Mechanical Testing and Research, Inc. The Ti loss to oxidation leading to formation of undesirable phases was addressed by using a 49-51 at % ratio of Ni to Ti, respectively, during ink synthesis. Notably, there is no presence of the Heusler phase, TiNi₂Sn, which is a common secondary phase in many synthesis procedures.

### Thermoelectric Properties

The TE properties for both pre- and post-annealing cases of a single cast sample are shown in FIGS. 5A-5C and its zT values, calculated from Eq. (1) in FIG. 5D. The TE performance is the same before and after long-term annealing, except for a ˜10% difference in thermal conductivity (see FIG. 5A) which translates into a ˜10% difference in zT values.

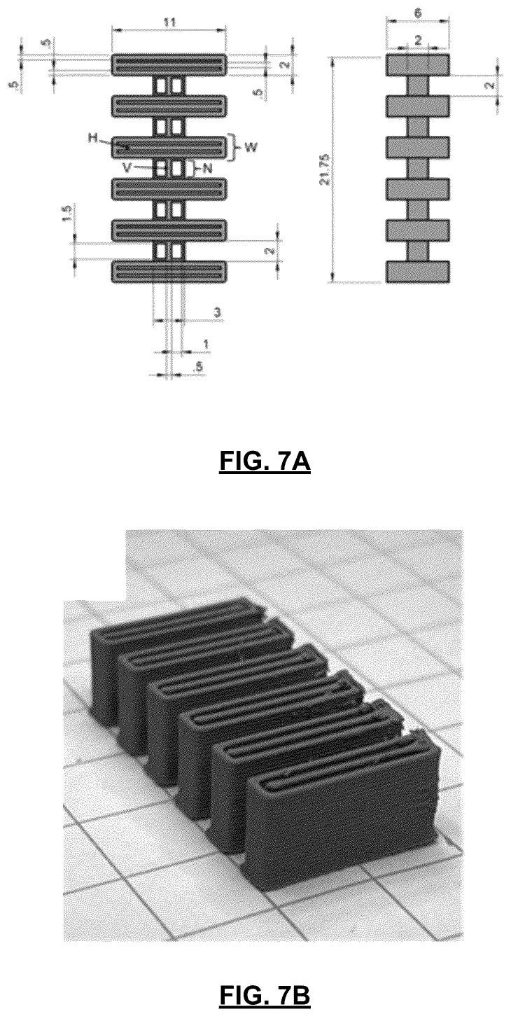

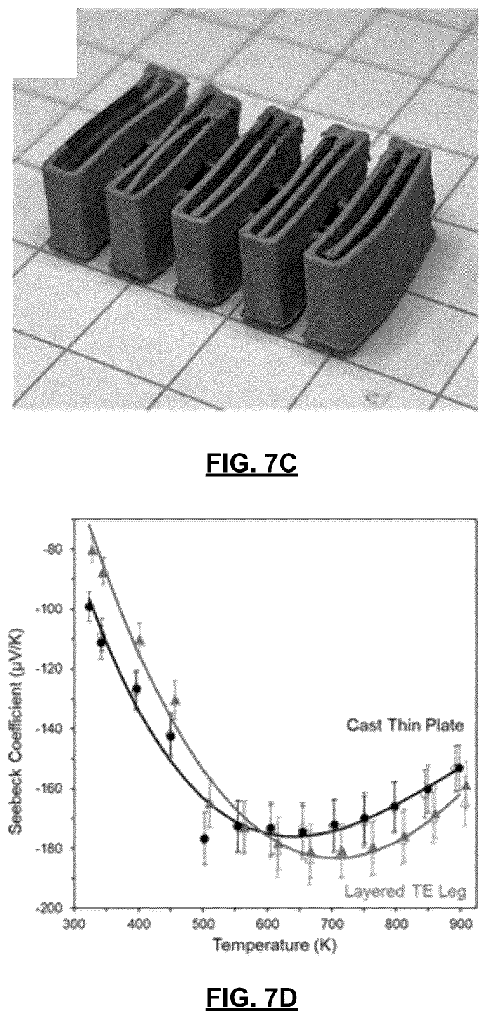

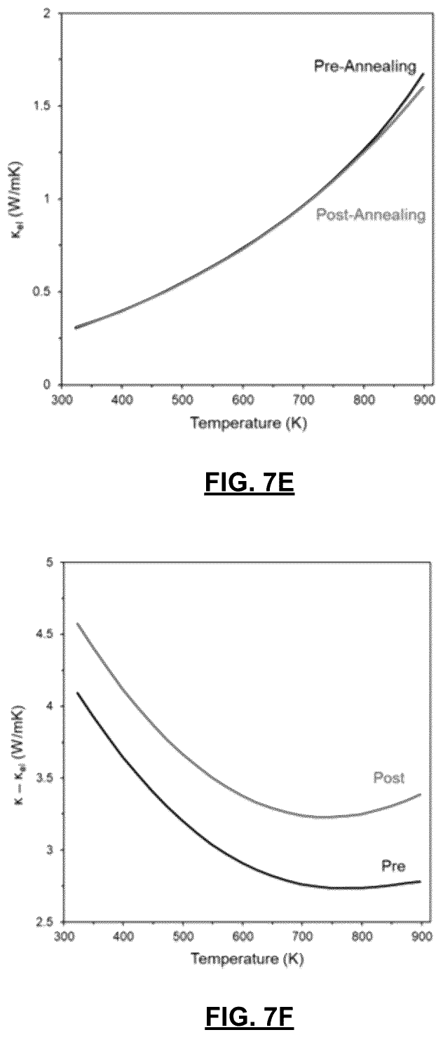

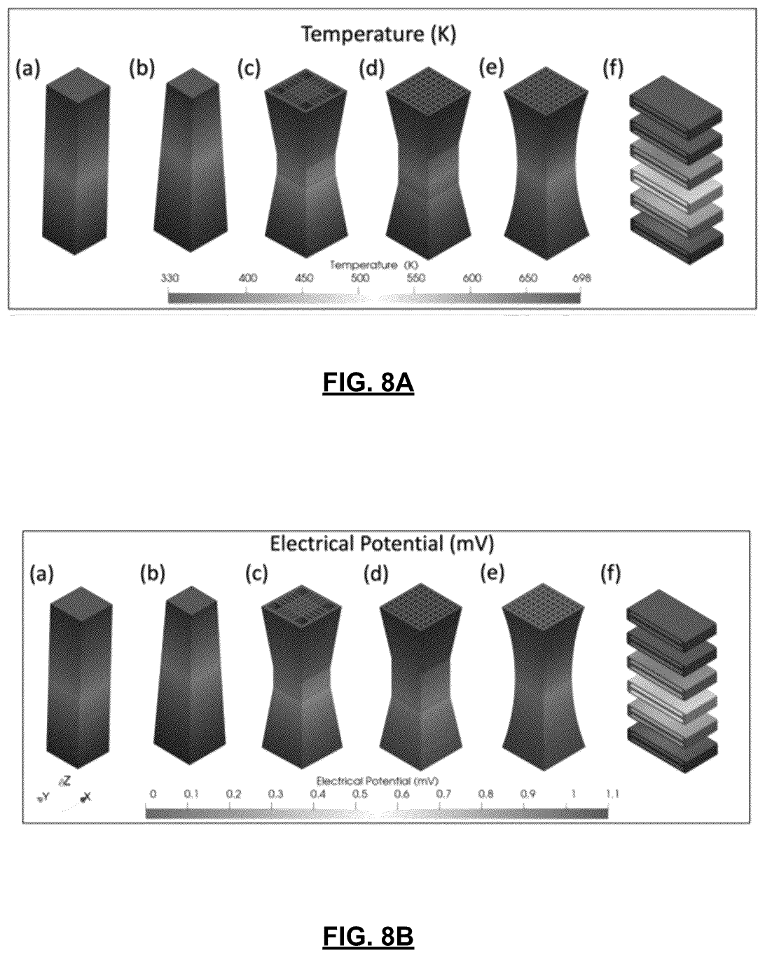

FIG. 5A shows that, in both pre- and post-annealing cases, the thermal conductivity decreases with increasing temperature until ˜600 K where it begins to increase due to bipolar contributions. As the total thermal conductivity is the sum of lattice and electronic contributions it can be split into these separate contributions by calculating κₑₗ using the Wiedmann-Franz law:

$${κ}_{e l} = LT / ρ \qquad ( 2 )$$

where κₑₗ is the electronic contribution to the thermal conductivity, L is the Lorenz number, T is temperature and ρ is electrical resistivity. Doing so using temperature-dependent Lorenz numbers calculated by a procedure used by May et al. shows that the increase in total thermal conductivity for the post-annealing state is due to an increase in lattice thermal conductivity (κ−κₑₗ), as shown in FIGS. 7E and 7F. This increase in lattice thermal conductivity is likely due to a reduction in phonon scattering by grain boundaries, as grains coarsened during the week-long annealing process.

As shown in FIG. 5B, the electrical resistivity for both pre- and post-annealing states is identical: it decreases monotonically with increasing temperature, which is consistent with semiconducting behavior. Similarly, the Seebeck coefficient, shown in FIG. 5C, is the same for both states: it is negative as electrons are the primary charge carriers (n-type) and its magnitude increases to a maximum of 176 μV/K at 648 K, above which it slowly decreases. The parabolic shape is a result of excitation across the band gap at higher temperatures which generates contributions from minority carriers (holes) subsequently decreasing the absolute value of the Seebeck coefficient. Deviations from the polynomial curve models in all three properties at ˜500 K can be attributed to the melting of the Sn phase (Tₘ=505 K), present in small amounts within the TiNiSn matrix, as shown in FIG. 4A.

The figure of merit zT calculated from Eq. (1) is shown in FIG. 5D. The curves for the pre- and post-annealing cases are identical at room temperature and begin to diverge with increasing temperature, due to differences in thermal conductivity. The pre-annealed material achieves a maximum zT of 0.50±0.05 at 848 K while the post-annealed material reaches 0.45±0.05 at 823 K. Thus, it is apparent that annealing at 850° C. for one week, after the reaction sintering step at 1000° C., provides no improvement in thermoelectric efficiency. FIG. 6A compares the temperature dependence of zT for the pre-annealed curve with those from the literature for other synthesis procedures for intrinsic TiNiSn, which all use powders, except for processes utilizing arc melting (AR). It is apparent from FIG. 6A that the disclosed process-a combination of powder- and melt processing-shows better zT values than the other powder-based processes, with the exception of a reaction sinter (RS) and hot isostatic pressing (HIP) approach, while also being compatible with additive manufacturing via ink printing.

A possible reason for a higher zT compared to other work could be the absence of commonly reported secondary phases TiNi₂Sn and Ti—Sn binary compounds, none of which are present in the disclosed specimens, as shown in FIG. 4A. Instead, the disclosed approach identifies less common secondary phases such as Ni₃Sn₄ and Ti₂Ni. Interestingly, it has been suggested that Ni₃Sn₄, due to its higher density, is effective at phonon scattering, subsequently decreasing thermal conductivity. Other processes achieve densities ranging from 86% to >99% in line with the 91% value achieved here. The arc melting (AR) approaches achieve larger zT through having little to no secondary phases, high densities, and small grain sizes.

### 3D Printed Layered TE Leg

To demonstrate the additive manufacturing capability of the process, complex lattice layered TE legs were 3D ink printed, before being subjected to debinding, partial Ni+Ti sintering and Sn-infiltration steps. A solid layered geometry was used as inspiration, based on COMSOL simulations showing that such a geometry results in higher thermal resistances and output electrical power in TE modules when compared to cuboid TE legs. The shape of the legs was found to be a key design variable affecting the TE performance of the devices. Legs with varying cross-section decrease the overall thermal conductance, thus increasing the temperature gradient between the hot and cold side as compared with legs with traditional cuboid-shaped shape and constant cross-sections. The large temperature gradient through the leg leads to a non-constant Seebeck coefficient, which produces the Thomson effect. Such a complex latticed layered TE leg is currently unattainable through any non-additive manufacturing approach and is very challenging to achieve without cracking via AM methods based on laser powder bed fusion. As shown in FIG. 7A, the layered leg consists of six wide sections (W), each 11×6×2 mm in volume, bisected by a horizontal strut (H). Connecting these six wide sections are five narrow sections (N), 3×2×2 mm in volume, bisected by a vertical strut (V).

The as-printed green-body TE leg is shown in FIG. 7B and the same TE leg, after debinding, Ni+Ti pre-sintering and Sn infiltration, is shown in FIG. 7C. During the debinding and Ni+Ti pre-sintering, the walls and interior lattice struts may occasionally deform due to the fragility of the part during debinding; this can be addressed through the addition of additional struts and spars, or other geometric design. Like for the cast thin plates, linear shrinkage was negligible (size discrepancy between FIGS. 7B and 7C is due to removal of one layer section for characterization between synthesis steps).

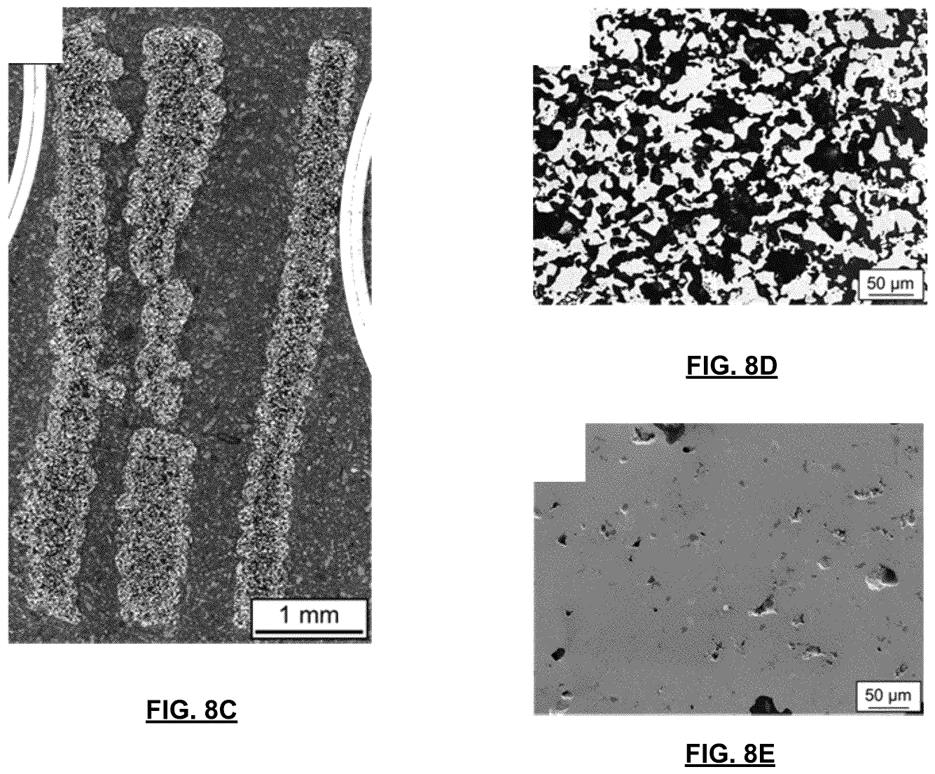

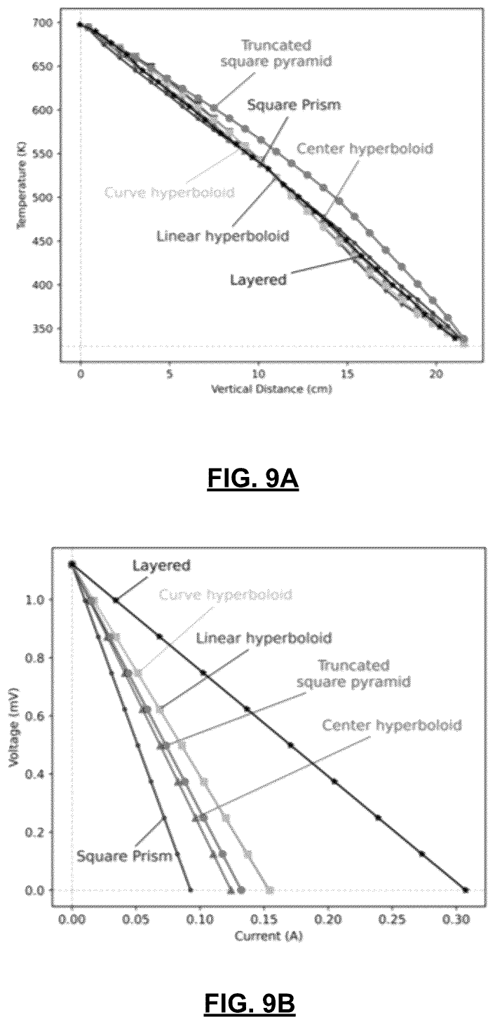

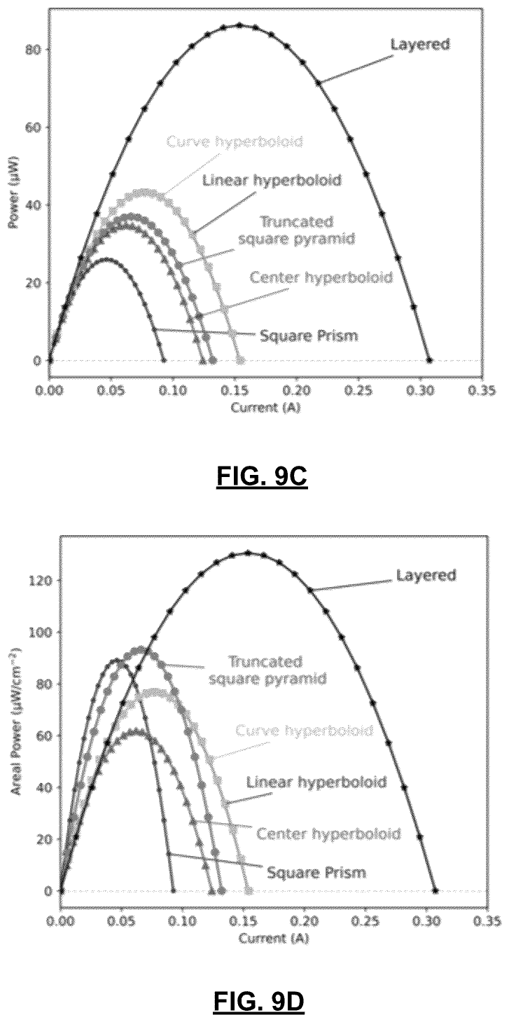

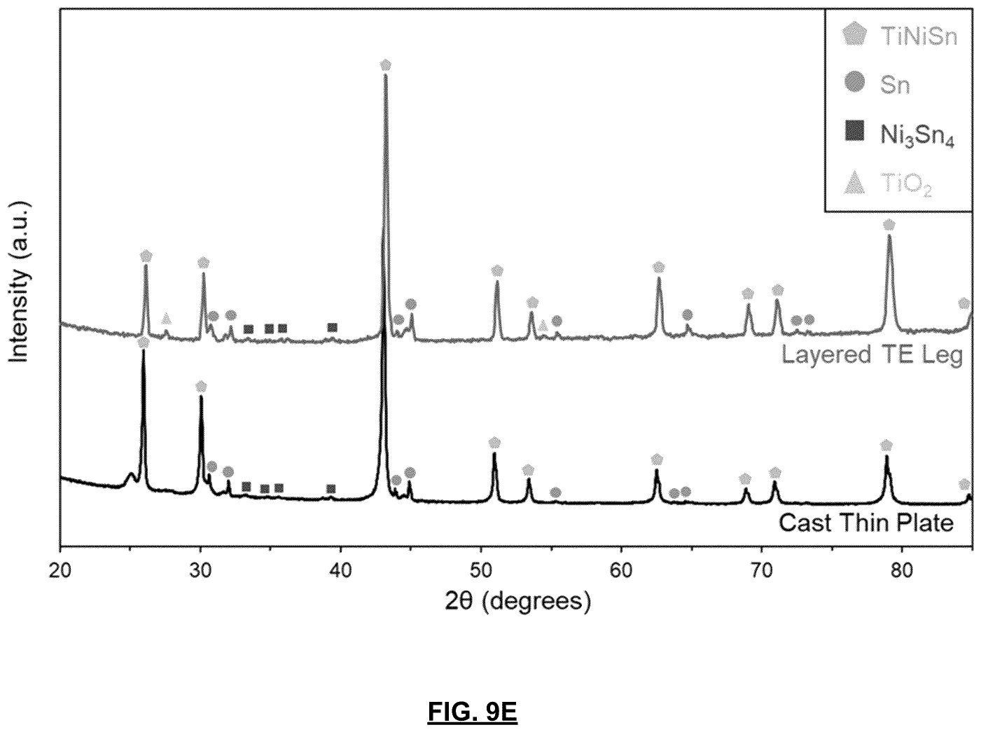

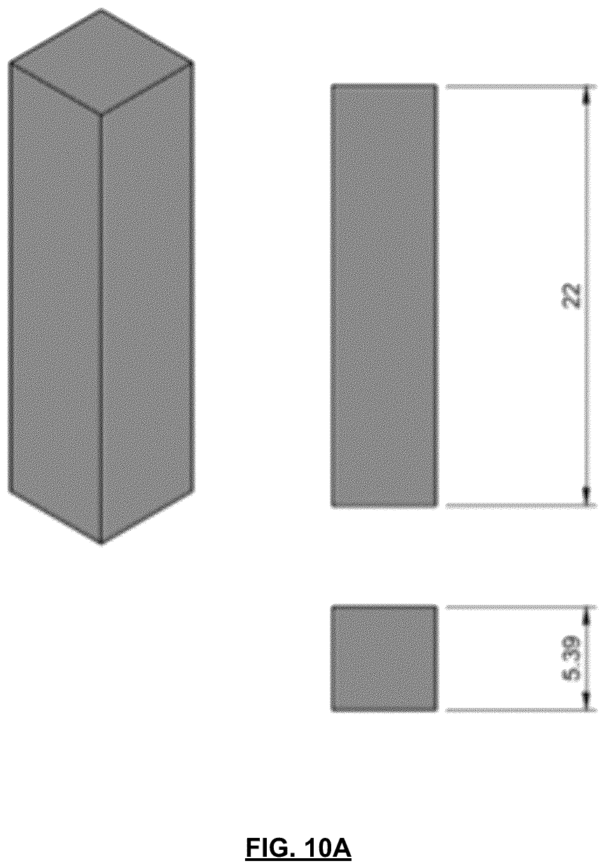

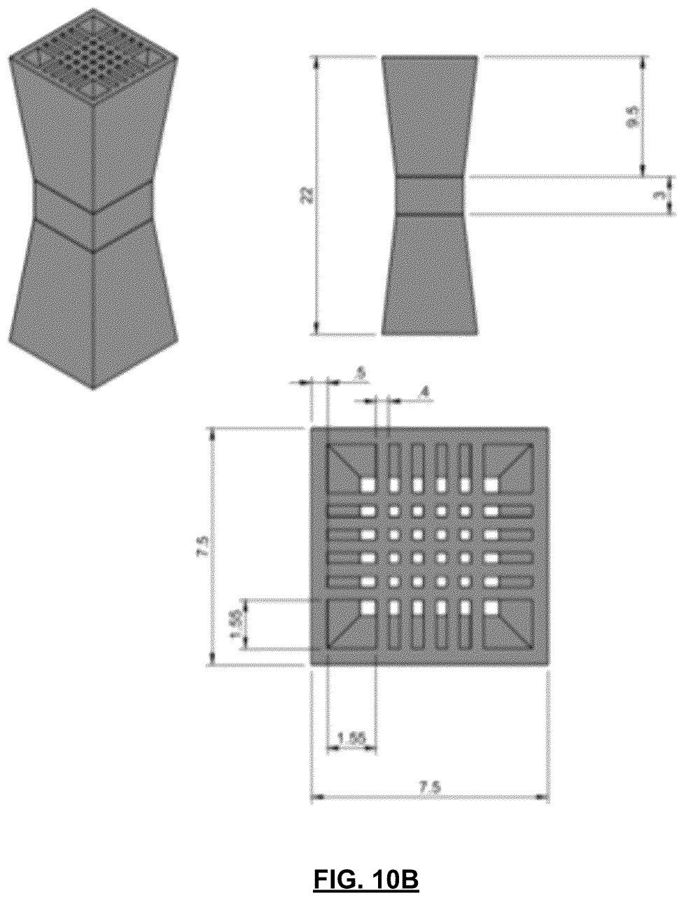

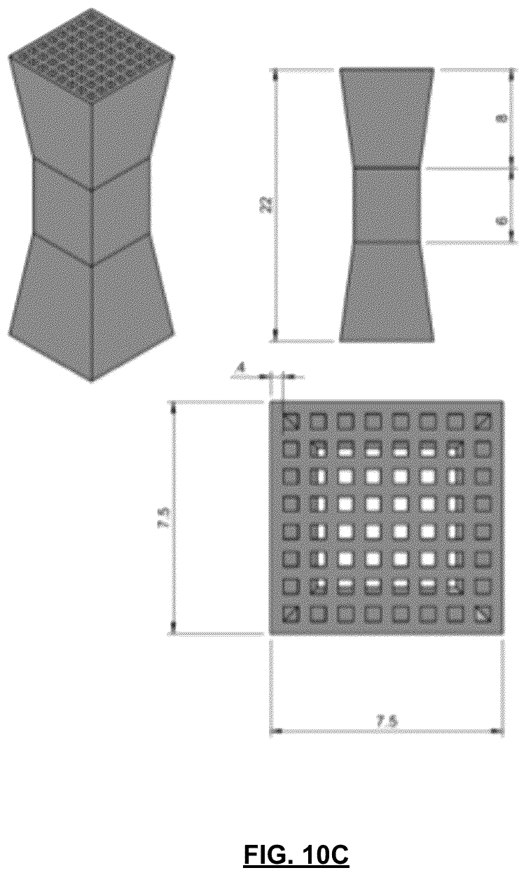

The microstructure for the printed TE leg, following debinding, Ni+Ti pre-sintering and Sn infiltration, is identical to that achieved for cast thin plates shown in FIGS. 8C-8E: a TiNiSn matrix containing ˜5% residual porosity and low volume fractions of additional phases. XRD (see FIG. 9E) and EDS analysis of the layered TE leg indicate the presence of the same secondary phases, at similar volume fractions, except for slightly increased TiO₂ probably due to a greater surface area. Due to the complex geometry of the TE leg, only the Seebeck coefficient could be meaningfully measured (see FIG. 7D). When compared to the pre-annealing cast thin plate, the TE leg demonstrates a similar parabolic curve with a peak value of −183 μV/K at 698 K, confirming that the TiNiSn phase exhibits TE properties (and thus zT values) on par with those achieved via existing powder-based synthesis procedures.

### FEM Modeling of Different Leg Geometries

To compare the thermoelectric performance of our printed layered TE leg, Finite Element Modeling (FEM) of the different leg geometries was conducted using the Multiphysics Object Oriented Simulation Environment (MOOSE) Framework. MOOSE is a massively parallel, open-source finite element framework for running multiphysics simulations. The backend of MOOSE relies on libMesh and PETSc for finite elements and numerical solvers, respectively. Modular design is used to organize the code, where complex systems are broken down into smaller, more manageable parts called modules that perform a specific function or task. MOOSE modules provide additional physics and functional capabilities. Modules can be combined to create larger and more complex systems. One such module is HeatConduction, which computes thermal and radiation transfer.

MOOSE tools were used to evaluate and compare the performance of the different thermoelectric leg geometries. Thermal effects from different thermal exchanges (conduction, convection and radiation) were evaluated for the different geometries (cuboid, pyramid, hyperboloid and layered). Computational meshes were generated using CUBIT™, with a base tetrahedron size of 0.01 mm.

Constant temperature boundary conditions were applied to the top and bottom surfaces. The bottom is designated as the hot side while the top is the cold side. The hot side temperature is prescribed as 698K and the cold side temperature is prescribed as 330K. For the simulation, three different modes of heat transfer are considered. Conduction is modeled using Fourier's law

$$\vec{q} = - k ∇ T \qquad ( 3 )$$

where \vec{q} is the heat flux, k is the thermal conductivity of the legs, and ∇T is the temperature gradient between hot and cold side. The legs are assumed to be insulated and therefore an adiabatic condition was applied around the sides and edges of the legs. Surface-to-surface radiative heat transfer occurs between the layers in the layered geometry. The total heat flux is the summation of gas gap conductance through the air \vec{q}_{gas} between the layers and the radiative heat flux \vec{q}_{rad}. The radiative thermal transfer is prescribed between the surfaces and between the layers, using

$${\vec{q}}_{r a d} = \frac{{σ}_{s}}{( \frac{1}{{ε}_{1}} - \frac{1}{{ε}_{2}} - 1 )} ( {T}_{1}^{4} - {T}_{2}^{4} ) \qquad ( 4 )$$

where σₛ is the Stefan-Boltzmann constant, ε₁ and ε₂ are the material emissivities, T₁ and T₂ are the temperatures of surfaces 1 and 2. The gas gap heat flux is taken as K_{gap}/D_{gap}, where K_{gap} is the gap conductance and D_{gap} is the distance of the gap.

To measure the electrical potentials generated, the temperature-dependent Seebeck coefficient is applied. The electrical potential at each nodal position can be determined using the following relationship

$$\vec{E} = S \vec{∇} T \qquad ( 5 )$$

where \vec{E} is the gradient of the electrical potential, and S is the Seebeck coefficient. Using these values, the current I and output power P of the thermoelectric is expressed as

$$I = \frac{S ∇ T}{R + {R}_{o}} \qquad ( 6 )$$

$$P = {I}^{2} {R}_{o} \qquad ( 7 )$$

where R is the combined internal electrical resistance, and Rₒ is the external electrical resistance. The material properties of TiNiSn were obtained. Seebeck coefficient was fit using a 2^{nd} order polynomial. The density of 6704 kg/m³ was obtained from literature. The emissivity was assumed to be 0.6. The gap conductance for air was estimated as 0.025 W/m²K.

### Modeling Results

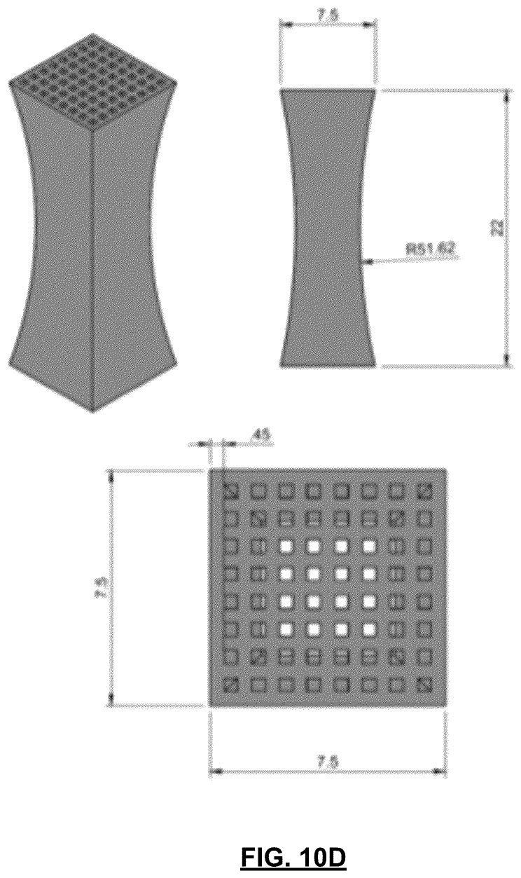

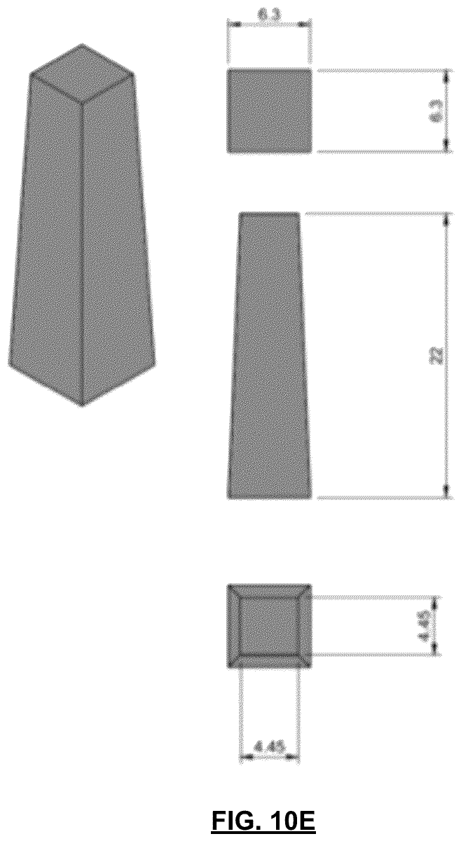

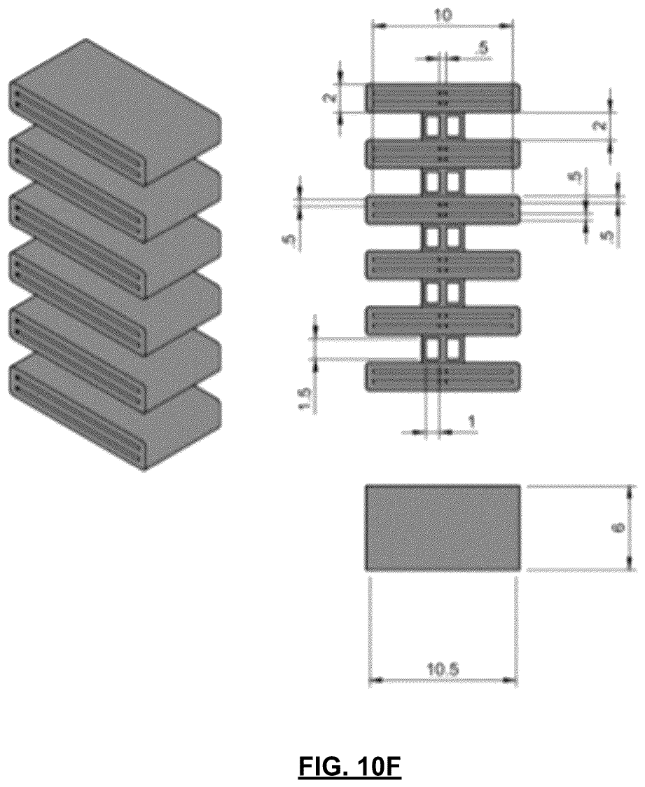

In all simulations, the steady-state analysis accounted for heat conduction and mechanical analysis within the leg and the electrical potential developed across the leg due to the Seebeck effect. The temperature and electrical potentials for the different geometries are shown in FIGS. 8A and 8B. The six different geometries have the same total height of 22 mm and approximately similar solid volume 641.65 mm³ (±0.065%). Models for six geometries were produced, one simple, commonly produced cuboid (a), a truncated square pyramid (b), three hyperboloids with varying internal spacing and outer surfaces (c-e) and one layered geometry (f). All hyperboloid structures feature an internal lattice structure. For center hyperboloid (c), the lattice is located primary in the center with a grid spacing of 0.4 mm in x- and y-directions and contain five struts. For the second and third hyperboloid (d and e), the structure is spread throughout the top surface lattice structure with a grid spacing of 0.445 mm. Schematics of the geometries tested are shown in FIGS. 10A-10F.

The temperature profile was extracted from each geometry. To capture the temperature deviation across the geometry as the contour can become smaller and larger, each geometry were sliced and binned across the vertical (z-axis) distance into 50 separate data point. Afterward, each bin was averaged to obtain the average slices temperature. FIG. 9A shows the temperature gradient from the hot to cold side of the leg for the six different geometries analyzed. Among the three different hyperboloid geometries, the curved and linear hyperboloids achieve the largest temperature gradients at the center point due to their reduced cross-sections. This effect is not as apparent in the center hyperboloid due to its central latticing, which maintains a more constant cross-sectional area throughout the leg. The truncated square pyramid demonstrates increasing temperature gradient due to decreasing cross-sectional area from the hot to cold side. The internal electrical resistance of the various geometries is the slope of the open circuit voltage versus short circuit current, as shown in FIG. 9B. As the internal electrical resistance is linked to the cross-sectional area, the latticed geometries have significantly larger resistance than the square prism. The layered geometry has the largest resistance due to its narrow sections between layers. Using Eq. 7 the power output for each geometry can be calculated and is shown in FIG. 9C. Due to the large thermal gradients and subsequent electrical potentials produced by the layered geometry it exhibits the largest power output. However, packing factors are important when comparing different leg geometries, since even though the geometries have identical internal volume, the project areas are different, which can lead to differences in the number of legs that can be packed in a given area. When comparing the different geometries power output per area, as shown in FIG. 9D, the layered leg achieves the peak power output due to its increased surface area for cooling. Furthermore, this will further reduce the thermal stress from thermal expansion. To improve the layered geometry legs, staggering of layers between legs can allow for interlocking thermoelectric couples decreasing project area and subsequently boosting output power per area. Additionally, the layered geometry can be further optimized by decreasing height to minimize wasted material on the cold side.

### Processing Considerations

The disclosed approach consists of four distinct steps: (i) ink fabrication, by suspending Ni and Ti powders into an ink with dissolved binder, with a viscosity suitable for casting or extrusion; (ii) casting of the ink, in air and at ambient temperature, within a mold or using a nozzle to print complex objects; (iii) a three-stage heat treatment, consisting of solvent evaporation, binder decomposition, and interdiffusion and sintering of Ni and Ti powders to form a porous, equiatomic NiTi preform; (iv) infiltration with liquid Sn of the porous NiTi perform, followed by atomic interdiffusion, transient liquid phase sintering, and homogenization to synthesize dense, equiatomic TiNiSn. This is to be compared to the traditional casting method comprising two steps: (i) melting and casting an ingot; and (ii) cutting and polishing TE legs. It can be also compared to the powder-metallurgy route where prealloyed powders are (i) first synthesized (via mechanical alloying or melt atomization); (ii) densified into ingots at high pressure and temperature, in inert atmosphere or vacuum; the resulting ingot is then (iii) cut and polished into legs. While the disclosed approach requires more steps, each step is relatively simple, requires no external pressure, results in no shrinkage, and is AM compatible. The ability to create dense, geometrically complex TE legs with little to no material loss opens new avenues for shape-optimized TE devices.

The Ni+Ti pre-sinter and the Sn-infiltration and reactive sintering steps are conducive to various doping strategies which may improve the TE performance of TiNiSn. For example, low-melting Bi (Tₘ=271° C.) or Sb (Tₘ=631° C.) can be added, in low concentrations (<0.125%), to the Sn melt (both show complete solubility in Sn above 631° C.) and then co-diffuse during the final reactive synthesis step to improve TE properties. Alternatively, during ink synthesis, dopants in solid powder form-such as Nb, Hf, Zr, Mn, or Cu—can be blended together with the Ni and Ti powders: these transition metals improve TE properties by occupying Ni or Ti superlattice sites or by segregating at grain boundaries. Simply optimizing the Ni:Ti atomic ratio also can improve zT, as excess Ni behaves as an intrinsic dopant capable of reducing thermal conductivity.

Beyond TiNiSn, the disclosed approach can be applied to various TE compounds in which one or more elements have a significantly lower melting point. A few requirements must be fulfilled: (i) to ensure pressureless infiltration, the melt should wet the solid precursor; (ii) to allow infiltration, the sintered precursor should exhibit open porosity, i.e., show a pore fraction above the percolation limit of ˜20%; (iii) to prevent collapse during infiltration, the precursor porosity should not exceed ˜80%, corresponding to the percolation thresholds for the solid preform. Examples of thermoelectric compounds which are amenable to the proposed process include other Half-Heusler compounds (e.g., NbFeSb or ZrCoSn), Zintl compounds (e.g., Yb₁₄MnSb₁₁ or CaZn₂Sb₂), as well as Mg₂Si— and La₃Te₄-based compounds. Also, rather than elemental powders, prealloyed powders can be used in the sintered preform; for example, SnSe₂ powders (pulverized from a cast alloy, with a relatively high congruent melting point, Tₘ=647° C.) can be partially sintered, infiltrated with liquid Sn (Tₘ=232° C.), and reacted to achieve the high-zT SnSe phase (congruently melting at 874° C.), despite the much lower melting points of both Sn and Se (Tₘ=232 and 221° C., respectively).

The half-Heusler compound TiNiSn is synthesized via the disclosed approach combining: (i) casting or printing of inks in which Ni+Ti powders are suspended; (ii) debinding and pre-sintering these powders into equiatomic NiTi with open porosity; and (iii) liquid Sn infiltration of, and interdiffusion with, the NiTi porous body to synthesize TiNiSn. The following features are observed: (1) Ink-cast thin plates of TiNiSn with relative density up to ˜91% and minimal undesirable secondary phases, achieve a maximum zT of 0.50±0.05 at 848 K; (2) Secondary phase content, following Sn infiltration, is highly sensitive to the porosity of the NiTi porous preform created by debinding and powder pre-sintering, as open porosity of 48.5% is desirable in the NiTi preform for complete reaction sintering to equiatomic TiNiSn; (3) Long-term annealing following Sn infiltration and interdiffusion provides no improvement in TE properties of ink-cast TiNiSn plates, but may instead increase thermal conductivity via grain growth as well as increase secondary phase content via oxidation; (4) Rather than ink-casting bulk objects, the ink can be 3D ink-printed into complex shapes, as demonstrated with TE legs printed into an open-lattice geometry with variable cross-section, which perform identically to ink-cast thin plates with regards to density, secondary phase content and Seebeck coefficient; (5) Different leg geometries were evaluated and the layered leg geometry achieved the highest thermal and electrical potential gradient. Layered geometry thus achieved the largest power output but was not optimal when normalizing for projected area; (6) Dopants can be introduced into this process by incorporation of solid powders such as Nb, Hf, Zr, Mn, or Cu into the ink or by infiltrating with liquid Sn alloyed with either Bi or Sb, all of which have been shown to improve thermoelectric performance; and (7) Infiltration and reaction sinter process can be extended beyond TiNiSn and could allow for AM fabrication of Zintl and other half-Heusler compounds.

To illustrate the interchangeability of hardware and software, items such as the various illustrative blocks, modules, components, methods, operations, instructions, and algorithms have been described generally in terms of their functionality. Whether such functionality is implemented as hardware, software or a combination of hardware and software depends upon the particular application and design constraints imposed on the overall system. Skilled artisans may implement the described functionality in varying ways for each particular application.

As used herein, the phrase “at least one of” preceding a series of items, with the terms “and” or “or” to separate any of the items, modifies the list as a whole, rather than each member of the list (e.g., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. No claim element is to be construed under the provisions of 35 U.S.C. § 112, sixth paragraph, unless the element is expressly recited using the phrase “means for” or, in the case of a method claim, the element is recited using the phrase “step for”.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language claims and to encompass all legal equivalents. Notwithstanding, none of the claims are intended to embrace subject matter that fails to satisfy the requirements of the applicable patent law, nor should they be interpreted in such a way.

1. A method for additive manufacturing of ternary-phase thermoelectric materials, comprising:
creating ink specimens;
solidifying, via solvent evaporation, the ink specimens into Ni powders and Ti powders;
debinding and pre-sintering the Ni powders and the Ti powders to form a porous NiTi skeleton;
infiltrating the porous NiTi skeleton with a transient liquid; and
reaction sintering NiTi of the porous NiTi skeleton and the transient liquid to reactively form TiNiSn.

2. The method of claim 1, wherein creating the ink specimens comprises creating the ink specimens via 3D ink extrusion.

3. The method of claim 2, wherein creating the ink specimens via 3D ink extrusion comprises 3D printing into a complex architecture.

4. The method of claim 1, wherein creating the ink specimens comprises creating the ink specimens via ink casting.

5. The method of claim 4, wherein creating the ink specimens via ink casting comprises ink casting into a mold.

6. The method of claim 1, wherein infiltrating the porous NiTi skeleton with the transient liquid comprises drawing the transient liquid, via capillary forces, into the porous NiTi skeleton.

7. The method of claim 6, wherein the transient liquid is liquid Sn.

8. A ternary-phase thermoelectric material, comprising:
a structure, wherein the structure is formed by creating ink specimens,
solidifying, via solvent evaporation, the ink specimens into Ni powders and Ti powders,
debinding and pre-sintering the Ni powders and the Ti powders to form a porous NiTi skeleton,
infiltrating the porous NiTi skeleton with a transient liquid, and
reaction sintering NiTi of the porous NiTi skeleton and the transient liquid to reactively form TiNiSn.

9. The ternary-phase thermoelectric material of claim 8, wherein creating the ink specimens comprises creating the ink specimens via 3D ink extrusion.

10. The ternary-phase thermoelectric material of claim 9, wherein creating the ink specimens via 3D ink extrusion comprises 3D printing into the structure.

11. The ternary-phase thermoelectric material of claim 8, wherein creating the ink specimens comprises creating the ink specimens via ink casting.

12. The ternary-phase thermoelectric material of claim 11, wherein creating the ink specimens via ink casting comprises ink casting into a mold of the structure.

13. The ternary-phase thermoelectric material of claim 8, wherein infiltrating the porous NiTi skeleton with the transient liquid comprises drawing the transient liquid, via capillary forces, into the porous NiTi skeleton.

14. The ternary-phase thermoelectric material of claim 8, wherein the transient liquid is liquid Sn.

15. A method for additive manufacturing of ternary-phase thermoelectric materials, comprising:
creating ink specimens;
solidifying, via solvent evaporation, the ink specimens into Ni powders and Ti powders;
debinding and pre-sintering the Ni powders and the Ti powders to form a porous NiTi skeleton;
infiltrating, via capillary forces, the porous NiTi skeleton with a liquid Sn; and
reaction sintering NiTi of the porous NiTi skeleton and the Sn to reactively form TiNiSn.

16. The method of claim 15, wherein creating the ink specimens comprises creating the ink specimens via 3D ink extrusion.

17. The method of claim 16, wherein creating the ink specimens via 3D ink extrusion comprises 3D printing into a complex architecture.

18. The method of claim 15, wherein creating the ink specimens comprises creating the ink specimens via ink casting.

19. The method of claim 18, wherein creating the ink specimens via ink casting comprises ink casting into a mold.

20. The method of claim 15, wherein the TiNiSn comprises minority phases and pores.
